(19) United States
(12) Patent Application Publication
(10) Pub. No.: US 2016/0242321 A1
(43) Pub. Date: Aug. 18, 2016

(54) MID-PLATES AND ELECTROMAGNETIC INTERFERENCE (EMI) BOARD LEVEL SHIELDS WITH EMBEDDED AND/OR INTERNAL HEAT SPREADERS

(71) Applicant: Laird Technologies, Inc., Earth City, MO (US)

(72) Inventors: Philip van Haaster, Corona, CA (US); Joseph C. Boetto, Hoffman Estates, IL (US); Paul W. Crotty, JR., East Stroudsburg, PA (US); Kenneth M. Robinson, Effort, PA (US); Jason L. Strader, Cleveland, OH (US)

(21) Appl. No.: 14/734,715

(22) Filed: Jun. 9, 2015

Related U.S. Application Data
(60) Provisional application No. 62/115,712, filed on Feb. 13, 2015.

(51) Int. Cl. H05K 7/20; B23P 15/26

(52) U.S. Cl. CPC H05K 7/20509; B23P 15/26

(57) ABSTRACT

According to various aspects, exemplary embodiments are disclosed of mid-plates and EMI shields for electronic devices. In an exemplary embodiment, a mid-plate generally includes one or more recessed portions along a surface of the mid-plate. A heat spreader is within the one or more recessed portions. Dielectric is along an outward-facing surface of the heat spreader. The dielectric inhibits the heat spreader from directly contacting and electrically shorting one or more components. In another exemplary embodiment, a board level shield (BLS) generally includes a cover having one or more recessed portions along an inner surface of the cover. A heat spreader is within the one or more recessed portions. Dielectric is along an outward-facing surface of the heat spreader, whereby the dielectric inhibits the heat spreader from directly contacting and electrically shorting one or more components when the one or more components are under the BLS.

### CROSS-REFERENCE TO RELATED APPLICATION

This patent application claims the benefit of and priority to U.S. Provisional Patent Application No. 62/115,712 filed Feb. 13, 2015. The entire disclosure of the above application is incorporated herein by reference.

### FIELD

The present disclosure generally relates to mid-plates and EMI board level shields including embedded and/or internal heat spreaders.

### BACKGROUND

This section provides background information related to the present disclosure which is not necessarily prior art.

Electrical components, such as semiconductors, transistors, etc., typically have pre-designed temperatures at which the electrical components optimally operate. Ideally, the pre-designed temperatures approximate the temperature of the surrounding air. But the operation of electrical components generates heat which, if not removed, will cause the electrical component to operate at temperatures significantly higher than its normal or desirable operating temperature. Such excessive temperatures may adversely affect the operating characteristics of the electrical component and the operation of the associated device.

To avoid or at least reduce the adverse operating characteristics from the heat generation, the heat should be removed, for example, by conducting the heat from the operating electrical component to a heat sink. The heat sink may then be cooled by conventional convection and/or radiation techniques. During conduction, heat may pass from the operating electrical component to the heat sink either by direct surface contact between the electrical component and heat sink and/or by contact of the electrical component and heat sink surfaces through an intermediate medium or thermal interface material (TIM). The thermal interface material may be used to fill the gap between thermal transfer surfaces, in order to increase thermal transfer efficiency as compared to having the gap filled with air, which is a relatively poor thermal conductor.

In addition to generating heat, the operation of electronic devices generates electromagnetic radiation within the electronic circuitry of the equipment. Such radiation may result in electromagnetic interference (EMI) or radio frequency interference (RFI), which can interfere with the operation of other electronic devices within a certain proximity. Without adequate shielding, EMI/RFI interference may cause degradation or complete loss of important signals, thereby rendering the electronic equipment inefficient or inoperable.

A common solution to ameliorate the effects of EMI/RFI is through the use of shields capable of absorbing and/or reflecting and/or redirecting EMI energy. These shields are typically employed to localize EMI/RFI within its source, and to insulate other devices proximal to the EMI/RFI source.

The term “EMI” as used herein should be considered to generally include and refer to EMI emissions and RFI emissions, and the term “electromagnetic” should be considered to generally include and refer to electromagnetic and radio frequency from external sources and internal sources. Accordingly, the term shielding (as used herein) broadly includes and refers to mitigating (or limiting) EMI and/or RFI, such as by absorbing, reflecting, blocking, and/or redirecting the energy or some combination thereof so that it no longer interferes, for example, for government compliance and/or for internal functionality of the electronic component system.

### SUMMARY

This section provides a general summary of the disclosure, and is not a comprehensive disclosure of its full scope or all of its features.

According to various aspects, exemplary embodiments are disclosed of mid-plates and EMI shields for electronic devices. In an exemplary embodiment, a mid-plate generally includes one or more recessed portions along a surface of the mid-plate. A heat spreader is within the one or more recessed portions. Dielectric is along an outward-facing surface of the heat spreader. The dielectric inhibits the heat spreader from directly contacting and electrically shorting one or more components.

In another exemplary embodiment, a board level shield (BLS) generally includes a cover having one or more recessed portions along an inner surface of the cover. A heat spreader is within the one or more recessed portions. Dielectric is along an outward-facing surface of the heat spreader, whereby the dielectric inhibits the heat spreader from directly contacting and electrically shorting one or more components when the one or more components are under the BLS.

Also disclosed are exemplary embodiments of methods relating to making mid-plates and EMI shields for electronic devices. In an exemplary embodiment, a method generally includes removing material from the mid-plate or BLS to thereby create one or more recessed portions along a surface of the mid-plate or BLS, providing a heat spreader within the one or more recessed portions, and providing dielectric along an outward-facing surface of the heat spreader. The dielectric inhibits the heat spreader from directly contacting and electrically shorting one or more components.

Exemplary embodiments of methods relating to providing shielding for one or more components on a substrate are also disclosed. In an exemplary embodiment, a method generally includes installing a shield to a substrate such that the one or more components are disposed under one or more recessed portions along an inner surface of the shield, wherein a heat spreader is within the one or more recessed portions and a dielectric is along an outward-facing surface of the heat spreader. The dielectric inhibits the heat spreader from directly contacting and electrically shorting the one or more components under the shield.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 illustrates a mid-plate for a smartphone according to a conventional design in which multiple external layers of material including a heat spreader are attached to an exterior surface of the mid-plate;

FIG. 2 illustrates a mid-plate for a smartphone according to an exemplary embodiment in which an embedded and/or internal heat spreader is at least partially disposed within an internal pocket or cavity of the mid-plate; and

FIG. 3 illustrates an EMI board level shield (BLS) according to an exemplary embodiment in which an embedded and/or internal heat spreader is at least partially disposed within an internal pocket or cavity of the BLS.

### DETAILED DESCRIPTION

Example embodiments will now be described more fully with reference to the accompanying drawings.

Smartphone thickness continues to decrease with each successive generation such that smartphone manufacturers continue to seek opportunities to reduce thickness while retaining or expanding on functionality. Currently, smartphones employ a mid-plate in their construction to isolate the screen from the battery and logic boards. The mid-plate may also be referred to herein as a midplate, mid plate, middle deck, or support member. The mid-plate is multifunctional in that it can serve as a mounting structure for other components (e.g., a heat spreader, etc.) and also act as a ground plane. Similarly, a board level shield (BLS) may also be multifunctional in that it can provide both shielding and thermal functions.

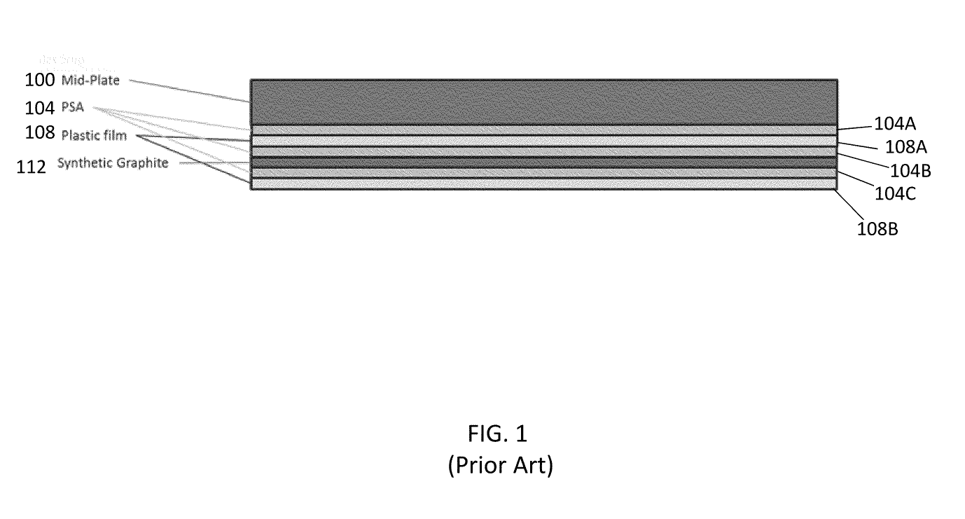

FIG. 1 illustrates a mid-plate 100 for a smartphone or other electronic device according to a conventional design. As shown in FIG. 1, there are multiple external layers of material 104, 108, 112 attached to an exterior bottom surface of the mid-plate 100. More specifically, there are three pressure sensitive adhesive (PSA) layers 104, a synthetic graphite layer 112, and two plastic film layers 108. The six layers 104, 108, 112 are stacked on top of each other in a stacked arrangement with the topmost PSA layer 104A adhesively attached to the exterior bottom surface of the mid-plate 100. The upper plastic film layer 108A is disposed or sandwiched between the upper and middle PSA layers 104A and 104B. The synthetic graphite layer 112 is disposed or sandwiched between the middle and lower PSA layers 104B and 104C. The lower plastic film layer 108B is on the bottom of the stack of materials and attached to the lower PSA layer 104C. The plastic film layers 108 are not thermally or electrically conductive, and thus provide electrical isolation and also inhibit graphite 112 from flaking off and migrating to other areas that may otherwise result in an electrical short. All of these material layers 104, 108, 112 are disposed entirely outside of or external to the mid-plate 100. For example, no portion of any of the material layers 104, 108, 112 are internal to or embedded within any portion of the mid-plate 100.

The inventors hereof have recognized that thickness is increased when a heat spreader is attached to an exterior surface of a mid-plate as shown in FIG. 1. This increased thickness, however, is contrary to the goals of smartphone manufacturers that continue to seek opportunities to reduce thickness while retaining or expanding on functionality. After recognizing the above, the inventors hereof sought to develop, have developed, and disclose herein exemplary embodiments of mid-plates and board level shields having at least partially embedded or internal heat spreaders. Example heat spreaders include synthetic graphite, natural graphite, other forms of pressed graphite or graphite fiber composites, graphene, graphene paper, CVD (chemical vapor deposition) diamond, CVD ceramics (e.g., aluminum nitride, aluminum silicon carbide (AlSiC), silicon carbide (SiC), etc.), higher thermal conductivity metal foils (e.g., copper, copper-molybdenum, high purity aluminum foil, etc.), ultra-thin heat pipes and vapor chambers, etc.

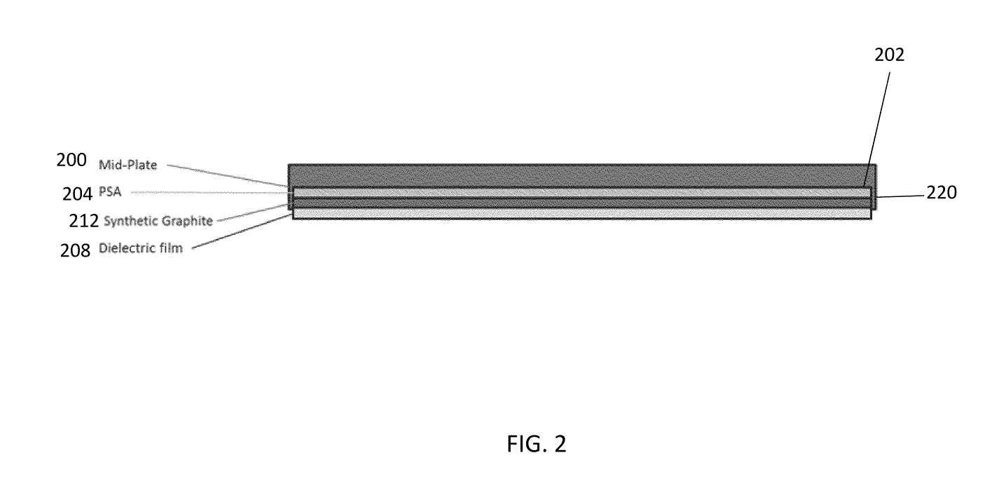

In exemplary embodiments, a mid-plate (e.g., 200 (FIG. 2), etc.) for an electronic device (e.g., a smartphone, etc.) includes one or more recesses or recessed portions (e.g., one or more internal pockets or cavities, etc.). For example, one or more pockets or cavities may be etched, embossed, machined, forged, etc. into or along a surface of a mid-plate. A heat spreader is provided within and/or along the one or more recessed portions of the mid-plate such that the heat spreader is at least partially embedded within, internal to, or disposed within the mid-plate. The mid-plate may include one or more sidewalls and a top having an inner surface. The inner surface of the top may include or define the one or more recesses or recessed portions.

The mid-plate may be electrically-conductive and operable as a ground plane for an electronic device, such as a smartphone, etc. For example, a smartphone may include a screen, a battery, one or more logic boards, and a mid-plate. The mid-plate may be operable as a ground plane for the smartphone. The mid-plate may also be operable to isolate the screen from the battery and the one or more logic boards. In addition, the mid-plate and the heat spreader may also define or provide a portion of a thermally-conductive heat path within the smartphone. For example, at least a portion of (or the entire) mid-plate may be thermally conductive. In which case, the mid-plate and the heat spreader may be used to establish or define at least a portion of a thermally-conductive heat path within the smartphone from a heat source (e.g., board-mounted heat generating electronic component, etc.) to a heat dissipating and/or heat removal structure (e.g., a heat sink, an exterior case or housing of the smartphone, heat spreader, heat pipe, etc.).

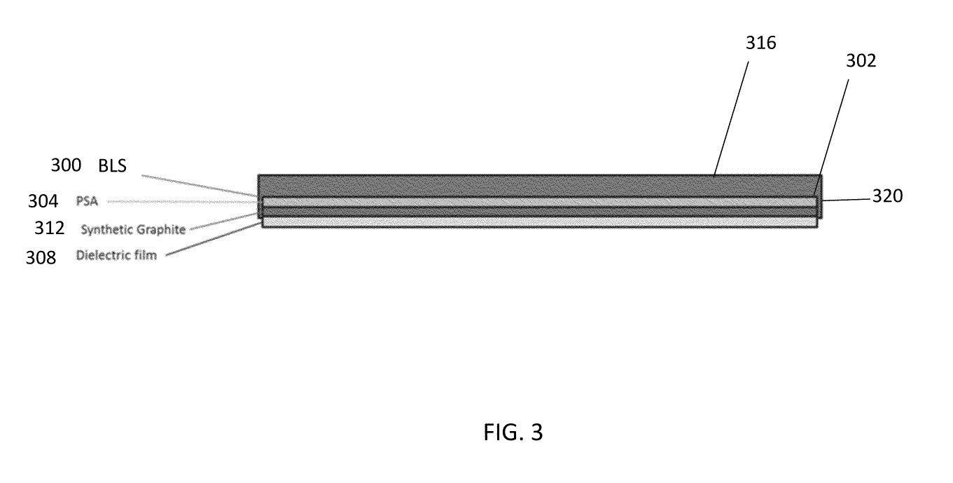

In other exemplary embodiments, a board level shield (BLS) (e.g., 300 (FIG. 3,) etc.) for an electronic device (e.g., a smartphone, etc.) includes a cover (broadly, a top or upper surface) and one or more sidewalls depending from (e.g., removably attached to, fixedly attached to, integrally connected with, etc.) the cover. An inner surface of the cover includes or defines one or more recesses or recessed portions (e.g., one or more internal pockets or cavities, etc.). For example, one or more pockets or cavities may be etched, embossed, machined, forged, etc. into or along an inner surface of the BLS. A heat spreader is provided within and/or along the one or more recessed portions of the BLS such that the heat spreader is at least partially embedded within, internal to, or disposed within the BLS. The sidewalls are configured for installation to a substrate (e.g., printed circuit board (PCB), etc.) generally about one or more components on the substrate such that the one or more components are under the BLS and/or within an interior or shielding enclosure cooperatively defined by the sidewalls and the cover. When the BLS is installed (e.g., soldered, etc.) on the substrate, the BLS is operable for shielding the one or more components that are within the interior or shielding enclosure cooperatively defined by the sidewalls and the cover. The BLS and heat spreader may also define or provide a portion of a thermally-conductive heat path within an electronic device, e.g., a smartphone, etc. For example, at least a portion of (or the entire) BLS may be thermally conductive. In which case, the BLS and the heat spreader may be used to establish or define at least a portion of a thermally-conductive heat path from a heat source (e.g., board-mounted heat generating electronic component, etc.) to a heat dissipating and/or heat removal structure (e.g., a heat sink, an exterior case or housing of the smartphone, heat spreader, heat pipe, etc.).

As disclosed herein, exemplary embodiments may reduce overall thickness by: (1) creating a mid-plate or BLS with one or more pockets in the mid-plate or BLS for a heat spreader (e.g., graphite, etc.); (2) by providing the option to use graphite sheets (or other suitable heat spreaders) uncoated with PET (polyethylene terephthalate) film; and (3) by the use and application of a relatively thin dielectric coating (e.g., via ink jet printing, a print nozzle, etc.) along and/or over the graphite to complete encapsulation and prevent graphite flaking and migration. In exemplary embodiments disclosed herein, a dielectric coating (e.g., 5 microns thick, etc.) may be deposited or dispensed (e.g., via an ink jet process, a print nozzle, other suitable process, etc.), which may help to reduce the overall layer thickness. As compared to the conventional design shown in FIG. 1, exemplary embodiments disclosed herein have less material layers, which also reduces overall thickness. For example, FIG. 1 illustrates six layers 104A, 104B, 104C, 108A, 108B, 112, while FIG. 2 illustrates only three layers 204, 208, 212.

Embedding a heat spreader at least partially within a mid-plate and/or BLS allows the overall thickness of the smartphone or other electronic device to be reduced. By way of example only, the thickness of a smartphone may be reduced by a minimum of approximately 30 microns in exemplary embodiments that employ a 25 micron thick synthetic graphite heat spreader attached to a mid-plate or BLS by a 5 to 10 micron thick adhesive (e.g., PSA, etc.) layer. In these exemplary embodiments, a dielectric layer of approximately 5 microns thick may be applied to the graphite (e.g., via an ink jet process, a print nozzle, other suitable process, etc.). The dielectric layer may electrically isolate the graphite from other smartphone components (e.g., logic boards, electronic components, battery, etc.). The dielectric layer may also encapsulate or coat the graphite to inhibit graphite flaking and migration.

In exemplary embodiments, dielectric (e.g., a dielectric coating, dielectric film, electrical insulation, etc.) is provided along and/or over a heat spreader within and/or along a recessed portion of a mid-plate or BLS. The dielectric electrically isolates the heat spreader from other components of the smartphone or other electronic device. The dielectric acts as an intermediary between the components and the heat spreader to prevent direct contact between the components and the heat spreader. The dielectric thus inhibits or prevents the heat spreader from electrically shorting components of the smartphone. By way of example, a dielectric coating may be deposited directly onto an outward-facing exposed surface of a heat spreader via an ink jet process, a print nozzle, or other suitable process. The dielectric coating may be cured with ultraviolet light. In an exemplary embodiment, the dielectric coating may provide electrical resistance greater than 4 gigaohms at 1000 volts with a 1 mm probe tip diameter and 100 gram weight. The dielectric coating may capable of withstanding or surviving lead-free reflow temperatures, such as a temperature of at least 260 degrees Celsius (e.g., 300 degrees Celsius, 350 degrees Celsius, etc.). The dielectric coating may comprise a blend of polymers, with acrylate polymers as the primary component, along with other components urethane, polyester and polyvinyl polymers, photo initiators, and other additives, etc. The dielectric coating may be disposed only along the outward-facing exposed surface of the heat spreader in some embodiments. In other embodiments, the dielectric coating may be disposed along a portion of the mid-plate or BLS in addition to the outward-facing exposed surface of the heat spreader.

FIG. 2 illustrates an exemplary embodiment of a mid-plate 200 for an electronic device, such as smartphone, tablet, etc. In this exemplary embodiment, the mid-plate 200 includes an internal pocket or cavity 202 (broadly, a recessed portion or recess). A heat spreader 212 is disposed at least partially within the internal pocket 202 such that the heat spreader 212 is at least partially embedded or internal to the mid-plate 200. As shown in FIG. 2, the heat spreader 212 does not protrude or extend outwardly beyond the bottom edge of the mid-plate's side portions 220. Accordingly, the heat spreader 212 is thus confined entirely within the pocket or space 202 underneath the mid-plate 200.

In this example, the mid-plate 200 includes a single pocket 202 defined by the cover 316 and sidewalls 320 (FIG. 3). In other embodiments, the mid-plate 200 may include more than one pocket 202, e.g., a pair of pockets that are side-by-side but spaced apart from each other and separated by a thicker portion of the mid-plate, etc. The pocket 202 may be formed by removing material from the mid-plate 200 to thereby reduce the material thickness at the location of the pocket 202. By way of example, the pocket 202 may be created by etching (e.g., chemical etching, laser etching, etc.) a sheet, strip, blank, or piece of electrically-conductive material (e.g., metal, metal alloy, etc.) before or after the material is stamped with a profile for the mid-plate 200. The etching process may take place before or after forming the stamped piece of material. Or, for example, the pocket 202 may be created by another process, such as embossing, machining, forging, etc. By way of example only, an exemplary embodiment includes a pocket 202 that is etched into a substrate or flat piece of metal before stamping the metal. In this example, the etching process may include applying a mask to the substrate and then removing the mask only at a location at which a pocket will be formed to thereby expose the area of the substrate that will be etched. The mask may be removed, for example, by laser ablation or with chemical dissolution of the photosensitized mask. The etching chemical (e.g., ferric chloride, etc.) may be introduced to dissolve the exposed metal and form the pocket in the substrate or flat piece of metal. The remaining mask is then removed from the substrate. Alternative embodiments may include one or more pockets formed at other locations and/or by a different method or process, such as embossing, machining, forging, etc. Accordingly, aspects of the present disclosure are not limited to any one particular process for creating or forming a pocket.

In this example, the heat spreader 212 comprises synthetic graphite that is adhesively attached to the mid-plate 200 with a pressure sensitive adhesive (PSA) 304. The PSA 304 is preferably electrically conductive and thermally conductive. Alternative embodiments may include other suitable heat spreaders, other adhesives, and/or other means for attaching a heat spreader to the BLS. Example heat spreaders include synthetic graphite, natural graphite, other forms of pressed graphite or graphite fiber composites, graphene, graphene paper, CVD (chemical vapor deposition) diamond, CVD ceramics (e.g., aluminum nitride, aluminum silicon carbide (AlSiC), silicon carbide (SiC), etc.), higher thermal conductivity metal foils (e.g., copper, copper-molybdenum, high purity aluminum foil, etc.), ultra-thin heat pipes and vapor chambers, etc.

Dielectric 208 (e.g., dielectric coating, dielectric film, electrical insulation, etc.) is provided along and/or over the heat spreader 212. The dielectric 208 electrically isolates the heat spreader 212 from components under the mid-plate 200. The dielectric 208 acts as an intermediary between the components and the heat spreader 212 to prevent direct contact between the components and the heat spreader 212. The dielectric 208 thus inhibits or prevents the heat spreader 212 from electrically shorting components of the electronic device. In FIG. 2, a lower portion of the dielectric 208 is shown protruding or extending outwardly beyond the bottom edge of the mid-plate's side portions 220. In other exemplary embodiments, the dielectric 208 may be confined entirely within the space or area underneath the mid-plate 200, such that no part of the dielectric 208 protrudes or extends outwardly beyond the bottom edge of the mid-plate's side portions 220.

By way of example, the dielectric 208 may comprise a dielectric coating deposited directly onto an outward-facing exposed surface of the heat spreader 212 via an ink jet process, a print nozzle, or other suitable process. The dielectric coating may then be cured with ultraviolet light. In an exemplary embodiment, the dielectric coating may then be cured with ultraviolet light, etc. In an exemplary embodiment, the dielectric coating may provide electrical resistance greater than 4 gigaohms at 1000 volts with a 1 mm probe tip diameter and 100 gram weight. The dielectric coating may capable of withstanding or surviving lead-free reflow temperatures, such as a temperature of at least 260 degrees Celsius (e.g., 300 degrees Celsius, 350 degrees Celsius, etc.). The dielectric coating may comprise a blend of polymers, with acrylate polymers as the primary component, along with other components urethane, polyester and polyvinyl polymers, photo initiators, and other additives, etc.

In some embodiments, the dielectric 208 may include one or more fillers and/or additives to achieve various desired outcomes. For example, the dielectric coating may include thermally-conductive filler such that the dielectric coating is also thermally conductive and operable as a thermal interface material. Examples of other fillers that may be added include pigments, plasticizers, process aids, flame retardants, extenders, tackifying agents, etc. The dielectric 208 may comprise a dielectric, thermally-conductive thermal interface material.

By way of example only, the heat spreader 212 may comprise synthetic graphite that is about 25 microns thick, the PSA 204 may be about 5 to 10 microns thick, and the dielectric 208 may be about 5 microns thick. In addition, the mid-plate 200 and the pocket 202 may have rectangular shapes or other suitable non-rectangular shapes. Other exemplary embodiments may be configured differently, such as having more or less than one pocket, having different shapes, and/or different thicknesses. The dimensions provided in this application are for purposes of illustration only as other exemplary embodiments may be sized differently, e.g., thicker or thinner, etc.

FIG. 3 illustrates an exemplary embodiment of a board level shield (BLS) 300 for an electronic device, such as smartphone, tablet, etc. In this exemplary embodiment, the BLS 300 includes a cover 316 (broadly, a top or upper surface) and sidewalls 320 depending from (e.g., attached to, integrally connected with, etc.) the cover 316. The sidewalls 320 are configured for installation to a substrate (e.g., printed circuit board (PCB), etc.) generally about one or more components on the substrate such that the one or more components are under the BLS 300 and/or within an interior or shielding enclosure cooperatively defined by the sidewalls 320 and the cover 316. When the BLS 300 is installed (e.g., soldered, etc.) on the substrate, the BLS 300 is operable for shielding the one or more components that are within the interior or shielding enclosure cooperatively defined by the sidewalls 320 and the cover 316.

The BLS 300 includes a pocket or cavity 302 (broadly, a recessed portion or recess). In this example, the BLS 300 includes a single pocket 302 defined by the cover 316 and sidewalls 320. In other embodiments, the BLS 300 may include more than one pocket 302, e.g., a pair of pockets that are side-by-side but spaced apart from each other and separated by a thicker portion of the BLS, etc. The pocket 302 may be formed by removing material from the material used to make the BLS 300 to thereby reduce the material thickness at the location of the pocket 302. For example, the pocket 302 may be formed by removing material from the cover 316 to thereby reduce the material thickness of the cover 316.

By way of example, the pocket 302 may be created by etching (e.g., laser etching, laser etching, etc.) a sheet, strip, blank, or piece of electrically-conductive material (e.g., metal, metal alloy, etc.) that has already been stamped with a flat pattern profile for the BLS 300. The flat profile pattern for the BLS 300 may include the cover 316 and sidewalls 320. The etching process may take place before or after forming the stamped piece of material. For example, the pocket 302 may be etched into the stamped piece of material before or after the stamped piece of material is folded or bent to position the sidewalls 320 generally perpendicular to the cover 316. Or, for example, the pocket 302 may be created by another process, such as embossing, machining, forging, etc. Accordingly, aspects of the present disclosure are not limited to any one particular process for creating or forming a pocket.

A heat spreader 312 is disposed at least partially within the internal pocket 302 such that the heat spreader 312 is at least partially embedded or internal to the BLS 300. As shown in FIG. 3, the heat spreader 312 does not protrude or extend outwardly beyond the bottom edge of the sidewalls 320. Accordingly, the heat spreader 312 is thus confined entirely within the space or area underneath the BLS 300.

In this example, the heat spreader 312 comprises synthetic graphite that is adhesively attached to the BLS 300 with a pressure sensitive adhesive (PSA) 304. The PSA 304 is preferably electrically conductive and thermally conductive. Alternative embodiments may include other suitable heat spreaders, other adhesives, and/or other means for attaching a heat spreader to the BLS. Example heat spreaders include synthetic graphite, natural graphite, other forms of pressed graphite or graphite fiber composites, graphene, graphene paper, CVD (chemical vapor deposition) diamond, CVD ceramics (e.g., aluminum nitride, aluminum silicon carbide (ALSIC), silicon carbide (SiC), etc.), higher thermal conductivity metal foils (e.g., copper, copper-molybdenum, high purity aluminum foil, etc.), ultra-thin heat pipes and vapor chambers, etc.

Dielectric 308 (e.g., dielectric coating, dielectric film, electrical insulation, etc.) is provided along and/or over the heat spreader 312. The dielectric 308 electrically isolates the heat spreader 312 from components under the BLS 300. The dielectric 308 acts as an intermediary between the components and the heat spreader 312 to prevent direct contact between the components and the heat spreader 312. The dielectric 308 thus inhibits or prevents the heat spreader 312 from electrically shorting components of the electronic device. In FIG. 3, a lower portion of the dielectric 308 is shown protruding or extending outwardly beyond the bottom edge of the sidewalls 320. In other exemplary embodiments, the dielectric 308 may be confined entirely within the space or area underneath the BLS 300, such that no part of the dielectric 308 protrudes or extends outwardly beyond the bottom edge of the sidewalls 320.

By way of example, the dielectric 308 may comprise a dielectric coating deposited directly onto an outward-facing exposed surface of the heat spreader 312 via an ink jet process. The dielectric coating may then be cured with ultraviolet light. In an exemplary embodiment, the dielectric coating may then be cured with ultraviolet light, etc. In an exemplary embodiment, the dielectric coating may provide electrical resistance greater than 4 gigaohms at 1000 volts with a 1 mm probe tip diameter and 100 gram weight. The dielectric coating may capable of withstanding or surviving lead-free reflow temperatures, such as a temperature of at least 260 degrees Celsius (e.g., 300 degrees Celsius, 350 degrees Celsius, etc.). The dielectric coating may comprise a blend of polymers, with acrylate polymers as the primary component, along with other components urethane, polyester and polyvinyl polymers, photo initiators, and other additives, etc.

In some embodiments, the dielectric 308 may include one or more fillers and/or additives to achieve various desired outcomes. For example, the dielectric coating may include thermally-conductive filler such that the dielectric coating is also thermally conductive and operable as a thermal interface material. Examples of other fillers that may be added include pigments, plasticizers, process aids, flame retardants, extenders, tackifying agents, etc. The dielectric 308 may comprise a dielectric, thermally-conductive thermal interface material.

In other embodiments, the BLS 300 may comprise one or more internal walls, dividers, or partitions that are separately attached (e.g., laser welded, resistance welded, etc.) or integrally attached to the BLS 300. For example, the BLS 300 may include an internal wall that improves EMI isolation as the internal wall would cooperate with the shield's cover 316 and sidewalls 320 to define two individual EMI shielding compartments. When the EMI BLS 300 is installed (e.g., adhesively attached, soldered to soldering pads, etc.) to a substrate (e.g., printed circuit board, etc.), components on the substrate may be positioned in different compartments such that the components are provided with EMI shielding by virtue of the EMI shielding compartments inhibiting the ingress and/or egress of EMI into and/or out of each EMI shielding compartment. In other exemplary embodiments, the EMI shield may not include or may be free of interior walls, dividers, or partitions such that the sidewalls and cover of the EMI shield generally define a single interior space or compartment.

By way of example only, the heat spreader 312 may comprise synthetic graphite that is about 25 microns thick, the PSA 304 may be about 5 to 10 microns thick, and the dielectric 308 may be about 5 microns thick. In addition, the BLS 300 and the pocket 302 may have rectangular shapes or other suitable non-rectangular shapes. Other exemplary embodiments may be configured differently, such as having more or less than one pocket, having different shapes, and/or different thicknesses. The dimensions provided in this application are for purposes of illustration only as other exemplary embodiments may be sized differently, e.g., thicker or thinner, etc.

The mid-plates (e.g., 200 (FIG. 2), etc.) and shields (e.g., 300 (FIG. 3), etc.) disclosed herein may be formed from a wide range of materials, which are preferably electrically-conductive materials. For example, a mid-plate and/or shield may be formed from metals or metal alloys, such as cold rolled steel (e.g., tin-plated cold rolled steel, etc.), sheet metal, stainless steel, copper alloys (e.g., tin-plated copper alloys, etc.), nickel-silver alloys (e.g., nickel-silver alloy 770, etc.), copper-nickel alloys, carbon steel, brass, copper, aluminum, copper-beryllium alloys, phosphor bronze, steel, alloys thereof, among other suitable electrically-conductive materials. The mid-plate and/or shield may also be formed from a plastic material coated with electrically-conductive material. In one exemplary embodiment, the mid-plate and/or shield may be formed from a sheet of nickel-silver alloy having a thickness of about 0.15 millimeters. The materials and dimensions provided herein are for purposes of illustration only, as the mid-plates and shields disclosed herein may be made from different materials and/or have different dimensions depending, for example, on the particular application, such as the electrical components to be shielded, space considerations within the overall electronic device, EMI shielding and heat dissipation needs, and other factors.

Also disclosed are exemplary embodiments of methods relating to making mid-plate and EMI shields. In an exemplary embodiment, a method generally includes removing material from a mid-plate or BLS to thereby create one or more recessed portions along a surface of the mid-plate or BLS, and providing a heat spreader within the one or more recessed portions. The process of removing material from the mid-plate or BLS may reduce thickness and provide up to 50% material thickness reduction at the one or more recessed portions. Example heat spreaders include synthetic graphite, natural graphite, other forms of pressed graphite or graphite fiber composites, graphene, graphene paper, CVD (chemical vapor deposition) diamond, CVD ceramics (e.g., aluminum nitride, aluminum silicon carbide (AlSiC), silicon carbide (SiC), etc.), higher thermal conductivity metal foils (e.g., copper, copper-molybdenum, high purity aluminum foil, etc.), ultra-thin heat pipes and vapor chambers, etc.

The heat spreader may be attached to the mid-plate or BLS, for example, with a pressure sensitive adhesive or other suitable adhesive, etc. Dielectric may be provided over and/or along the outward-facing exposed surface of the heat spreader. The dielectric inhibits the mid-plate or BLS from directly contacting and electrically shorting one or more components as the components would instead contact the dielectric. In this example method, the mid-plate or BLS may be etched to create the one or more recessed portions. The dielectric may be provided by coating dielectric along the outward-facing exposed surface of the heat spreader. For example, the method may include depositing a dielectric coating (e.g., via an ink jet process, a print nozzle, etc.) along the outward-facing exposed surface of the heat spreader, and then curing the dielectric coating with ultraviolet light.

The method may include stamping a flat pattern partial profile into a piece of material whereby the flat pattern partial profile includes a BLS cover and one or more sidewalls of the BLS, and then etching the stamped piece of material to thereby create the one or more recessed portions. The method may further include forming the stamped piece of material before or after etching the stamped piece of material by bending, folding, or drawing portions of the stamped piece of material that define the one or more sidewalls. The method may additionally include laser welding an internal wall to the inner surface of the BLS cover. The internal wall, the cover, and one or more sidewalls of the shield may cooperatively define a plurality of individual EMI shielding compartments, such that different components on a substrate are positionable in different compartments and are provided with EMI shielding by virtue of the EMI shielding compartments inhibiting the ingress and/or egress of EMI into and/or out of each EMI shielding compartment. Also, the method may include integrally forming the BLS cover and one or more sidewalls depending from the cover from a single piece of electrically-conductive material such that the BLS cover and the one or more sidewalls have a monolithic or single piece construction.

Exemplary embodiments of methods relating to providing shielding for one or more components on a substrate are also disclosed. In an exemplary embodiment, a method generally includes installing a shield to a substrate such that one or more components are disposed under a heat spreader, which is within one or more recessed portions along an inner surface of the shield. Dielectric may be provided along and/or over the outward-facing exposed surface of the heat spreader, such that the dielectric will be between the shield and the one or more components. The dielectric inhibits the heat spreader from directly contacting and electrically shorting the one or more components under the shield.

In exemplary embodiments, the EMI shield includes a cover, top, or upper surface and one or more sidewalls. The one or more sidewalls may comprise a single sidewall, may comprise a plurality of sidewalls that are separate or discrete from each other, or may comprise a plurality of sidewalls that are integral parts of a single-piece EMI shield, etc. In exemplary embodiments, the EMI shield's cover or upper surface and the one or more sidewalls may be integrally formed (e.g., stamped, bent, folded, etc.) from a single piece of electrically-conductive material so as to have a monolithic construction. The shield's cover or upper surface may be integrally formed with the sidewalls such that the sidewalls depend downwardly relative to the cover or upper surface. In other exemplary embodiments, the EMI shield's cover or upper surface may be made separately and not integrally with the sidewalls. In some embodiments, the EMI shield may comprise a two-piece shield in which the shield's cover or lid is removable from and reattachable to the sidewalls.

In some exemplary embodiments, the EMI shield may include one or more interior walls, dividers, or partitions that are attached to and/or integrally formed with the EMI shield. In such embodiments, the shield's cover, sidewalls, and interior walls may cooperatively define a plurality of individual EMI shielding compartments. When the EMI shield is installed (e.g., adhesively attached, soldered to soldering pads, etc.) to a substrate (e.g., printed circuit board, etc.), components on the substrate may be positioned in different compartments such that the components are provided with EMI shielding by virtue of the EMI shielding compartments inhibiting the ingress and/or egress of EMI into and/or out of each EMI shielding compartment. In other exemplary embodiments, the EMI shield may not include or may be free of interior walls, dividers, or partitions such that the sidewalls and cover of the EMI shield generally define a single interior space or compartment.

In some exemplary embodiments, the EMI shield's cover or upper surface may include a generally flat, planar and/or central pick-up surface configured for use in handling the EMI shield with pick-and-place equipment (e.g., vacuum pick-and-place equipment, etc.). The pick-up surface may be configured for use as a pick-up area that may be gripped or to which suction may be applied by the pick-and-place equipment for handling during, for example, fabrication of the shield and/or installation of the shield to a PCB. The central location of the pick-up surface may allow for balanced manipulation of the shield during handling. In other exemplary embodiments, the EMI shield may, for example, have tabs at corners and/or along side edges for use as pick-up surfaces in addition to or in place of centrally located pick-up surfaces.

In some exemplary embodiments, the EMI shield's cover or upper surface may include one or more apertures or holes, which may facilitate solder reflow heating interiorly of the shield and/or enable cooling of the components under the shield and/or permit visual inspection of the components beneath the shield. In some of these exemplary embodiments, the holes may be sufficiently small to inhibit passage of interfering EMI. The particular number, size, shape, orientation, etc. of the holes may vary depending, for example, on the particular application (e.g., sensitivity of the electronics where more sensitive circuitry may necessitate the use of smaller diameter holes, etc.). In still other exemplary embodiments, the shield may include a cover or upper surface that does not have any such holes.

In some exemplary embodiments, at least a portion of the mid-plate or BLS may be thermally conductive to help establish or define at least a portion of a thermally-conductive heat path from a heat source (e.g., board-mounted heat generating electronic component of an electronic device, etc.) to a heat dissipating and/or heat removal structure, such as a heat sink, an exterior case or housing of an electronic device (e.g., cellular phone, smart phone, tablet, laptop, personal computer, etc.), heat spreader, heat pipe, etc. Generally, the heat source may comprise any component or device that has a higher temperature than the mid-plate or BLS during operation or otherwise provides or transfers heat to the mid-plate or BLS regardless of whether the heat is generated by the heat source or merely transferred through or via the heat source. For example, the mid-plate or BLS may be electrically conductive and thermally conductive. In this example, one or more thermal interface materials (e.g., compliant or conformable thermal interface pad, putty, or gap filler, etc.) may be disposed along (e.g., adhesively attached via a pressure sensitive adhesive (PSA) tape, etc.) an outer surface and/or inner surface (e.g., along a recessed portion, recess, internal pocket or cavity, etc.) of the mid-plate or BLS. The thermal interface material may be configured to make contact (e.g., direct physical contact, etc.) with a heat dissipating device or heat removal structure. By way of further example, the thermal interface material may comprise a conformable and/or flowable thermal interface material having sufficient compressibility, flexibility, deformability, and/or flowability to allow the thermal interface material to relatively closely conform to the size and outer shape of the heat dissipating device or heat removal structure, thereby removing air gaps therebetween. The thermal interface may also be a form-in-place material such that it can be dispensed in place onto the mid-plate or BLS.

In embodiments that include one or more thermal interface materials, a wide variety of materials may be used for any of the one or more thermal interface materials (TIMs) in those exemplary embodiments. For example, the one or more TIMs may be formed from materials that are better thermal conductors and have higher thermal conductivities than air alone. The one or more TIMs may comprise thermal interface materials from Laird Technologies, such as Tflex™ 300 series thermal gap filler materials, Tflex™ 600 series thermal gap filler materials, Tpcm™ 580 series phase change materials, Tpcm™ 780 series phase change materials Tpli™ 200 series gap fillers, and/or Tgrease™ 880 series thermal greases, etc. By way of further example, a TIM may be molded from thermally-conductive and electrically-conductive elastomer. A TIM may comprise a thermally-conductive compliant material or thermally conductive interface material formed from ceramic particles, metal particles, ferrite EMI/RFI absorbing particles, metal or fiberglass meshes in a base of rubber, gel, grease or wax, etc. Exemplary embodiments may include a TIM with a thermal conductivity higher than 6 W/mK, less than 1.2 W/mK, or other values between 1.2 and 6 W/mk. For example, a TIM may be used that has a thermal conductivity higher than air's thermal conductivity of 0.024 W/mK, such as a thermal conductivity of about 0.3 W/mK, of about 3.0 W/mK, or somewhere between 0.3 W/mK and 3.0 W/mK, etc.

A TIM may include compliant or conformable silicone pads, non-silicone based materials (e.g., non-silicone based gap filler materials, thermoplastic and/or thermoset polymeric, elastomeric materials, etc.), silk screened materials, polyurethane foams or gels, thermal putties, thermal greases, thermally-conductive additives, etc. A TIM may be configured to have sufficient conformability, compliability, and/or softness to allow the TIM material to closely conform to a mating surface when placed in contact with the mating surface, including a non-flat, curved, or uneven mating surface. A TIM may comprise an electrically conductive soft thermal interface material formed from elastomer and at least one thermally-conductive metal, boron nitride, and/or ceramic filler, such that the soft thermal interface material is conformable even without undergoing a phase change or reflow. The TIM may be a non-metal, non-phase change material that does not include metal and that is conformable even without undergoing a phase change or reflow. A TIM may comprise a thermal interface phase change material.

A TIM may comprise one or more conformable thermal interface material gap filler pads having sufficient deformability, compliance, conformability, compressibility, flowability, and/or flexibility for allowing a pad to relatively closely conform (e.g., in a relatively close fitting and encapsulating manner, etc.) to the size and outer shape of another component. Also, the thermal interface material gap filler pad may be a non-phase change material and/or be configured to adjust for tolerance or gap by deflecting.

In some exemplary embodiments, the thermal interface material may comprise a non-phase change gap filler, gap pad, or putty that is conformable without having to melt or undergo a phase change. The thermal interface material may be able to adjust for tolerance or gaps by deflecting at low temperatures (e.g., room temperature of 20° C. to 25° C., etc.). The thermal interface material may have a Young's modulus and Hardness Shore value considerably lower than copper or aluminum. The thermal interface material may also have greater percent deflection versus pressure than copper or aluminum.

In some exemplary embodiments, the thermal interface material comprises T-flex™ 300 ceramic filled silicone elastomer gap filler or T-flex™ 600 boron nitride filled silicone elastomer gap filler, which both have a Young's modulus of about 0.000689 gigapascals. Accordingly, exemplary embodiments may include thermal interface materials having a Young's module much less than 1 gigapascal. T-flex™ 300 ceramic filled silicone elastomer gap filler and T-flex™ 600 boron nitride filled silicone elastomer gap filler have a Shore 00 hardness value (per the ASTMD2240 test method) of about 27 and 25, respectively. In some other exemplary embodiments, the thermal interface material may comprise T-pli™ 200 boron nitride filled, silicone elastomer, fiberglass reinforced gap filler having a Shore 00 hardness of about 70 or 75. Accordingly, exemplary embodiments may include thermal interface materials having a Shore 00 hardness less than 100. T-flex™ 300 series thermal gap filler materials generally include, e.g., ceramic filled silicone elastomer which will deflect to over 50% at pressures of 50 pounds per square inch and other properties shown below. T-flex™ 600 series thermal gap filler materials generally include boron nitride filled silicone elastomer, which recover to over 90% of their original thickness after compression under low pressure (e.g., 10 to 100 pounds per square inch, etc.), have a hardness of 25 Shore 00 or 40 Shore 00 per ASTM D2240. Tpli™ 200 series gap fillers generally include reinforced boron nitride filled silicone elastomer, have a hardness of 75 Shore 00 or 70 Shore 00 per ASTM D2240. Tpcm™ 580 series phase change materials are generally non-reinforced films having a phase change softening temperature of about 122 degrees Fahrenheit (50 degrees Celsius). Tgrease™ 880 series thermal grease is generally a silicone-based thermal grease having a viscosity of less than 1,500,000 centipoises. Other exemplary embodiments may include a TIM with a hardness of less 25 Shore 00, greater than 75 Shore 00, between 25 and 75 Shore 00, etc.

In some exemplary embodiments, one or more EMI or microwave absorbers may be disposed along an outer surface and/or inner surface (e.g., along a recessed portion, recess, internal pocket or cavity, etc.) of the mid-plate or BLS. In embodiments that include one or more EMI or microwave absorbers, a wide range of materials may be used, such as carbonyl iron, iron silicide, iron particles, iron-chrome compounds, metallic silver, carbonyl iron powder, SENDUST (an alloy containing 85% iron, 9.5% silicon and 5.5% aluminum), permalloy (an alloy containing about 20% iron and 80% nickel), ferrites, magnetic alloys, magnetic powders, magnetic flakes, magnetic particles, nickel-based alloys and powders, chrome alloys, and any combinations thereof. The EMI absorbers may comprise one or more of granules, spheroids, microspheres, ellipsoids, irregular spheroids, strands, flakes, powder, and/or a combination of any or all of these shapes.

Exemplary embodiments disclosed herein may provide one or more (but not necessarily any or all) of the following advantages over some existing mid-plates and/or board level EMI shields. For example, exemplary embodiments disclosed herein may allow for reducing the overall product thickness (1) by creating a mid-plate and/or BLS with one or more pockets in the mid-plate and/or BLS for a graphite heat spreader (or other suitable heat spreader), (2) by providing the option to use graphite sheets uncoated with PET (polyethylene terephthalate) film; and (3) by the use and application of a relatively thin dielectric coating (e.g., via ink jet printing, a print nozzle, etc.) over and/or along the graphite to complete encapsulation and prevent graphite flaking and migration. In exemplary embodiments disclosed herein, ink jet printing of a relatively thin dielectric coating (e.g., 5 microns thick, etc.) may also help to reduce the overall layer thickness. Exemplary embodiments disclosed herein have less material layers as compared to the conventional designs.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms, and that neither should be construed to limit the scope of the disclosure. In some example embodiments, well-known processes, well-known device structures, and well-known technologies are not described in detail. In addition, advantages and improvements that may be achieved with one or more exemplary embodiments of the present disclosure are provided for purposes of illustration only and do not limit the scope of the present disclosure, as exemplary embodiments disclosed herein may provide all or none of the above mentioned advantages and improvements and still fall within the scope of the present disclosure.

Specific dimensions, specific materials, and/or specific shapes disclosed herein are example in nature and do not limit the scope of the present disclosure. The disclosure herein of particular values and particular ranges of values for given parameters are not exclusive of other values and ranges of values that may be useful in one or more of the examples disclosed herein. Moreover, it is envisioned that any two particular values for a specific parameter stated herein may define the endpoints of a range of values that may be suitable for the given parameter (i.e., the disclosure of a first value and a second value for a given parameter can be interpreted as disclosing that any value between the first and second values could also be employed for the given parameter). For example, if Parameter X is exemplified herein to have value A and also exemplified to have value Z, it is envisioned that parameter X may have a range of values from about A to about Z. Similarly, it is envisioned that disclosure of two or more ranges of values for a parameter (whether such ranges are nested, overlapping or distinct) subsume all possible combination of ranges for the value that might be claimed using endpoints of the disclosed ranges. For example, if parameter X is exemplified herein to have values in the range of 1-10, or 2-9, or 3-8, it is also envisioned that Parameter X may have other ranges of values including 1-9, 1-8, 1-3, 1-2, 2-10, 2-8, 2-3, 3-10, and 3-9.

The terminology used herein is for the purpose of describing particular example embodiments only and is not intended to be limiting. As used herein, the singular forms “a”, “an” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on”, “engaged to”, “connected to” or “coupled to” another element or layer, it may be directly on, engaged, connected or coupled to the other element or layer, or intervening elements or layers may be present. In contrast, when an element is referred to as being “directly on,” “directly engaged to”, “directly connected to” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

The term “about” when applied to values indicates that the calculation or the measurement allows some slight imprecision in the value (with some approach to exactness in the value; approximately or reasonably close to the value; nearly). If, for some reason, the imprecision provided by “about” is not otherwise understood in the art with this ordinary meaning, then “about” as used herein indicates at least variations that may arise from ordinary methods of measuring or using such parameters. For example, the terms “generally”, “about”, and “substantially” may be used herein to mean within manufacturing tolerances.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath”, “below”, “lower”, “above”, “upper” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The foregoing description of the embodiments has been provided for purposes of illustration and description. It is not intended to be exhaustive or to limit the disclosure. Individual elements, intended or stated uses, or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

1. A mid-plate for an electronic device, the mid-plate comprising:
one or more recessed portions along a surface of the mid-plate;
a heat spreader within the one or more recessed portions; and
dielectric along an outward-facing surface of the heat spreader, whereby the dielectric inhibits the heat spreader from directly contacting and electrically shorting one or more components.

2. The mid-plate of claim 1, wherein the dielectric comprises a dielectric coating along the outward-facing surface of the heat spreader.

3. The mid-plate of claim 2, wherein the dielectric coating is deposited via an ink jet process and cured with ultraviolet light.

4. The mid-plate of claim 1, wherein:
the heat spreader is adhesively attached to the mid-plate with a pressure sensitive adhesive; and
the heat spreader comprises synthetic graphite.

5. The mid-plate of claim 1, wherein:
the heat spreader is a synthetic graphite heat spreader having a thickness of about 25 microns;
the synthetic graphite heat spreader attached to the mid-plate by an adhesive layer having a thickness of about 5 to 10 microns; and
the dielectric has a thickness of about 5 microns.

6. The mid-plate of claim 1, wherein the one or more recessed portions include one or more pockets etched into the mid-plate.

7. The mid-plate of claim 1, wherein a thickness of the mid-plate at the one or more recessed portions is less than a thickness of the mid-plate along a perimeter of the mid-plate.

8. The mid-plate of claim 1, wherein the one or more recessed portions have a reduced thickness defined by removal of a portion of the material from which the mid-plate is made.

9. A smartphone comprising a screen, a battery, one or more logic boards, and the mid-plate of claim 1, wherein the mid-plate is operable as a ground plane for the smartphone and operable to isolate the screen from the battery and the one or more logic boards.

10. A board level shield (BLS) suitable for use in providing electromagnetic interference (EMI) shielding for one or more components on a substrate, the BLS comprising:
a cover having one or more recessed portions along an inner surface of the cover;
a heat spreader within the one or more recessed portions; and
dielectric along an outward-facing surface of the heat spreader, whereby the dielectric inhibits the heat spreader from directly contacting and electrically shorting one or more components when the one or more components are under the BLS.

11. The BLS of claim 10, wherein the dielectric comprises a dielectric coating along the outward-facing surface of the heat spreader.

12. The BLS of claim 11, wherein the dielectric coating is deposited via an ink jet process and cured with ultraviolet light.

13. The BLS of claim 10, wherein:
the heat spreader is adhesively attached to the cover with a pressure sensitive adhesive; and
the heat spreader comprises synthetic graphite.

14. The BLS of claim 10, wherein:
the heat spreader is a synthetic graphite heat spreader having a thickness of about 25 microns;
the synthetic graphite heat spreader attached to the mid-plate by an adhesive layer having a thickness of about 5 to 10 microns; and
the dielectric has a thickness of about 5 microns.

15. The BLS of claim 10, wherein:
the one or more recessed portions include one or more pockets etched into the cover; and/or
a thickness of the cover at the one or more recessed portions is less than a thickness of the mid-plate along a perimeter of the cover; and/or
the one or more recessed portions have a reduced thickness defined by removal of a portion of the material from which the cover is made.

16. The BLS of claim 10, further comprising one or more sidewalls depending from the cover and configured for installation to the substrate generally about the one or more components on the substrate.

17. A method of making a mid-plate or electromagnetic interference (EMI) board level shield (BLS), the method comprising:
removing material from the mid-plate or BLS to thereby create one or more recessed portions along a surface of the mid-plate or BLS;
providing a heat spreader within the one or more recessed portions; and
providing dielectric along an outward-facing surface of the heat spreader, whereby the dielectric inhibits the heat spreader from directly contacting and electrically shorting one or more components.

18. The method of claim 17, wherein:
removing material comprises etching the mid-plate or BLS to create the one or more recessed portions; and/or
providing dielectric comprises coating dielectric along the outward-facing surface of the heat spreader.

19. The method of claim 17, wherein:
providing dielectric comprises depositing a dielectric coating via an ink jet process along the outward-facing surface of the heat spreader and then curing the dielectric coating with ultraviolet light; and/or
the method further comprises attaching the heat spreader to the mid-plate or BLS with a pressure sensitive adhesive; and/or
the heat spreader comprises synthetic graphite; and/or
the method further comprises stamping a flat pattern partial profile into a piece of material whereby the flat pattern partial profile includes a cover and one or more sidewalls of the BLS, wherein removing material comprises removing material from the stamped piece of material to thereby create the one or more recessed portions; and forming the stamped piece of material by bending, folding, or drawing portions of the stamped piece of material that define the one or more sidewalls.

20. A method relating to providing shielding for one or more components on a substrate, the method comprising installing a shield to the substrate such that the one or more components are disposed under one or more recessed portions along an inner surface of the shield, wherein a heat spreader is within the one or more recessed portions and a dielectric is along an outward-facing surface of the heat spreader, whereby the dielectric inhibits the heat spreader from directly contacting and electrically shorting the one or more components under the shield.
